(19) United States
(12) Patent Application Publication
(10) Pub. No.: US 2003/0174954 A1
(43) Pub. Date: Sep. 18, 2003

(54) Multi-mode interference waveguide-including semiconductor laser diode module, fiber-type optical amplifier, optical relay and optical communication system

(75) Inventors: Kiichi Hamamoto, Tokyo (JP); Masaki Ohya, Tokyo (JP)

Correspondence Address: McGinn & Gibb, PLLC, Suite 200, 8321 Old Courthouse Road, Vienna, VA, 22182-3817, US

(73) Assignee: NEC Corporation, Tokyo (JP)

(21) Appl. No.: 10/388,221

(22) Filed: Mar. 14, 2003

(30) Foreign Application Priority Data
Mar. 14, 2002 (JP) 2002-070312

(51) Int. Cl. G02B 6/26; H01S 5/00

(52) U.S. Cl. 385/39; 372/43

(57) ABSTRACT

In a semiconductor laser diode module, a semiconductor laser diode including a multi-mode interference type active waveguide is provided.

### BACKGROUND OF THE INVENTION

1. Field of the Invention

The present invention relates to a semiconductor laser diode module capable of generating a wavelength-stabilized output signal at a lower drive voltage and a lower power consumption, a fiber-type optical amplifier, an optical relay and an optical communication system using such a semiconductor laser diode module.

2. Description of the Related Art

In a prior art optical communication system at a speed such as 40 Gbps higher than the conventional speed such as 10 Gbps, in order to improve the signal-to-noise (S/N) ratio characteristics, a Raman amplifier is used in a fiber-type optical amplifier (see: JP-A-2000-098433).

On the other hand, in a dense wavelength division multiplexing (DWDM) optical communication system, a plurality of semiconductor laser diode modules for generating light beams having different center wavelengths are required. In this case, in order to flatten the gain, at least three semiconductor laser diode modules are required in each optical relay.

As communication demands have become remarkably increased and borderless in the world, high speed, long-distance and large capacity optical communication systems such as a submarine cable DWDM optical communication system have been developed. In such a submarine cable DWDM optical communication system, a power supply line as well as optical fibers is provided in a cable to supply a power to optical relays. In this case, the maximum voltage applied to the optical relays is limited by the insulating coating of the cable to avoid the breakdown thereof. As a result, the maximum voltage of the series of semiconductor laser diode modules of each relay unit is set to be about 5V, for example.

In a submarine cable DWDM optical communication system to which the fiber-type amplifier using the Raman amplifier is applied, however, the following problems may occur.

First, since a higher excited energy is required, each of the semiconductor laser diode modules needs a higher output, so that a drive voltage for the semiconductor laser diode modules needs to be higher than 2V such as about 2V to 2.5V. As a result, since the maximum voltage of the series of semiconductor laser diode modules is about 5V, the number of the semiconductor laser diode modules per optical relay is 2 at most, so that it is impossible to flatten the gain.

Secondly, since the drive voltage for the semiconductor laser modules is higher than 2V, the power consumption thereof is increased, so that, if each of the semiconductor laser diode modules includes a cooler element such as a Peltier element, the cooler element has to be increased in size, which increases the size of the semiconductor laser diode modules. Note that when the size of the semiconductor laser diode modules is increased, a board for mounting the semiconductor laser diode modules is also increased in size.

Finally, since the power consumption of the semiconductor laser diode modules is increased, the temperature thereof is increased, so that the wavelengths thereof fluctuate. When the wavelengths of the semiconductor laser diode modules fluctuate, a wavelength stabilizing mechanism such as a grating-associated optical fiber may be required, which increases the manufacturing cost, and also, fluctuation and noise may be generated by the mode hopping phenomenon in the light beam, which is disadvantageous in the system.

### SUMMARY OF THE INVENTION

It is an object of the present invention to provide a semiconductor laser diode module capable of generating a wavelength-stabilized output signal at a lower drive voltage and a lower power consumption.

Another object is to provide a fiber-type optical amplifier, an optical relay and an optical communication system using such a semiconductor laser diode module.

According to the present invention, in a semiconductor laser diode module, a semiconductor laser diode including a multi-mode interference type waveguide is provided.

### BRIEF DESCRIPTION OF THE DRAWINGS

The present invention will be more clearly understood from the description set forth below, with reference to the accompanying drawings, wherein:

FIG. 1 is a diagram illustrating a first embodiment of the semiconductor laser diode module according to the present invention;

FIG. 2A is a perspective view of the semiconductor laser diode of FIG. 1;

FIG. 2B is a plan view of the semiconductor laser diode module of FIG. 2A;

FIG. 2C is a cross-sectional view of the semiconductor laser diode module of FIG. 2A;

FIGS. 3A, 3B, 3C and 3D are graphs for explaining the characteristics of the semiconductor laser diode of FIG. 2;

FIG. 4 is a block circuit diagram illustrating an optical communication system to which the semiconductor laser diode module of FIG. 1 is applied;

FIG. 5 is a detailed block diagram of the optical relay of FIG. 4;

FIG. 6 is a detailed block circuit diagram of the fiber-type optical amplifier of FIG. 5;

FIG. 7 is a diagram illustrating a second embodiment of the semiconductor laser diode module according to the present invention;

FIG. 8 is a block circuit diagram illustrating an optical communication system to which the semiconductor laser diode module of FIG. 7 is applied;

FIG. 9 is a detailed block diagram of the optical relay of FIG. 8;

FIG. 10 is a detailed block circuit diagram of the fiber-type optical amplifier of FIG. 9;

FIGS. 11 and 12 are diagrams illustrating modifications of FIG. 1;

FIG. 13A is a perspective view illustrating a modification of FIG. 2A;

FIG. 13B is a plan view of the modification of FIG. 13A; and

FIG. 13C is a cross-sectional view of the modification of FIG. 13A.

### DESCRIPTION OF THE PREFERRED EMBODIMENTS

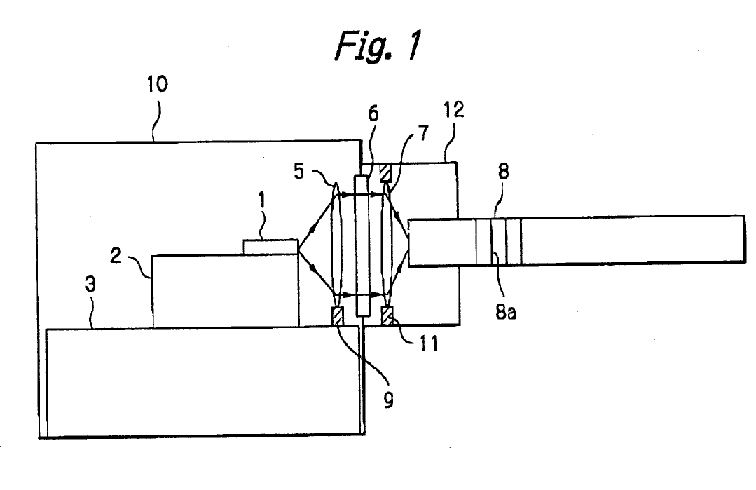

In FIG. 1, which illustrates a first embodiment of the semiconductor laser diode module according to the present invention, a multi-mode interference (MMI)-type semiconductor laser diode 1 is fixed to a heat sink 2 which is mounted on a carrier 3. Note that the carrier 3 usually includes a cooler element such as a Peltier element in a non-submarine cable communication system.

The MMI-type semiconductor laser diode 1 has a front facet for emitting a light beam having a wavelength of about 1400 to 1500 nm which is transmitted via a collimating lens 5, a glass window 6 and a coupling lens 7 to focus on a grating-associated optical fiber 8 with a grating 8a for stabilizing the wavelength of the light beam.

The collimating lens 5 is held by a lens holder 9 on the carrier 3.

The MMI-type semiconductor laser diode 1, the heat sink 2, the carrier 3) the collimating lens 5 and the lens holder 9 are packaged by a package 10 which has the size of the conventional butterfly package. Also, the coupling lens 7 is held by a lens holder 11 in a cylindrical member 12 which also fixes the grating-associated optical fiber 8 to the package 10 through the glass window 6.

A drive current and a temperature of the MMI-type semiconductor laser diode 1 are controlled by a laser diode drive unit (not shown), so that the output and wavelength of the light beam emitted from the MMI-type semiconductor laser diode 1 can be controlled.

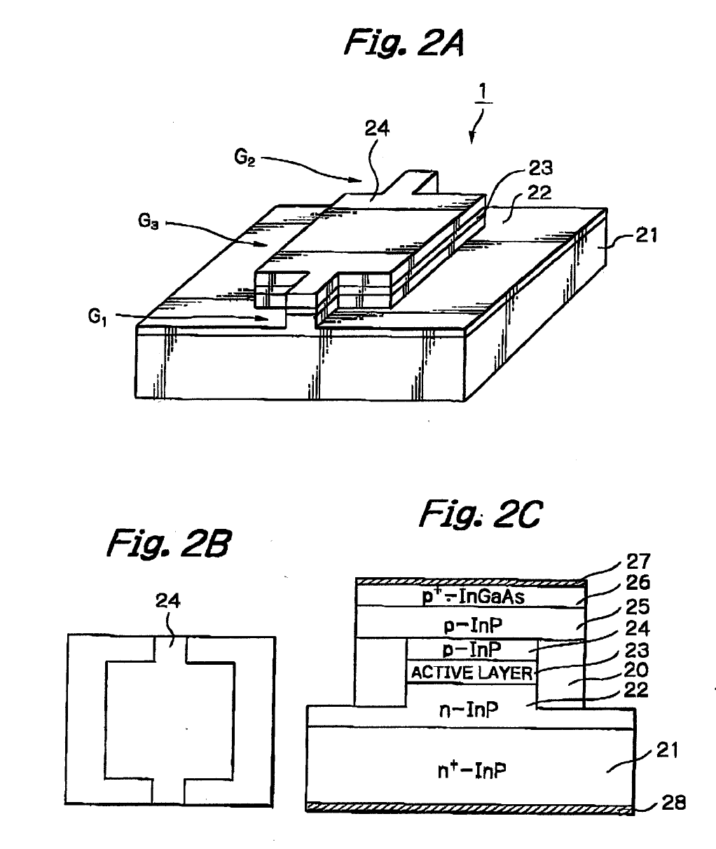

The MMI-type semiconductor laser diode 1 of FIG. 1 has an optical waveguide structure including a 1×N (N=1, 2, . . . ) multi-mode interference (MMI) type optical waveguide section as illustrated in FIGS. 2A, 2B and 2C (see: JP-A-11-068241, JP-A-11-068242, JP-A-2001-168450, Kiichi Hamamoto et al., “Single-traverse-mode Active-MMI 1.5 μm-InGaAsP Buried-Hetero Laser Diode”, European Conference on Integrated Optics, PD51-PD54, Apr. 1997, and U.S. Pat. No. 6,205,163). In FIGS. 2A, 2B and 2C, note that a 1×1 MMI type optical waveguide section is illustrated for simplifying the description.

In FIGS. 2A, 2B and 2C, the MMI-type semiconductor laser diode 1 is constructed by an n⁺-type InP substrate 21, an n-type InP buffer 22, an InGaAsP/InP multi-quantum well active layer 23 and a p-type InP clad layer 24 and a blocking layer 20 (pnpn-type blocking layer or Fe-doped InP semi-insulating layer). In this case, a one-port single-mode waveguide G₁ is provided at a front facet to which an anti-reflection coating (not shown) Is applied, and an N-port single-mode waveguide G₂ is provided at a rear facet to which a high-reflection coating (not shown) is applied. In addition, as illustrated in FIG. 2C, a p-type InP burying layer 25 and a p⁺-type InGaAs cap layer 26 are formed on the blocking layer 20 and the InP clad layer 24. Further, as illustrated in FIG. 2C, a p-type electrode 27 and an n-type electrode 28 are formed. In this case, a 1×N multi-mode interference type waveguide G₃ is interposed between the single-mode waveguides G₁ and G₂ Further, the width of the multi-mode interference type waveguide G₃ is larger than that of each of the-single-mode waveguides G₁ and G₂.

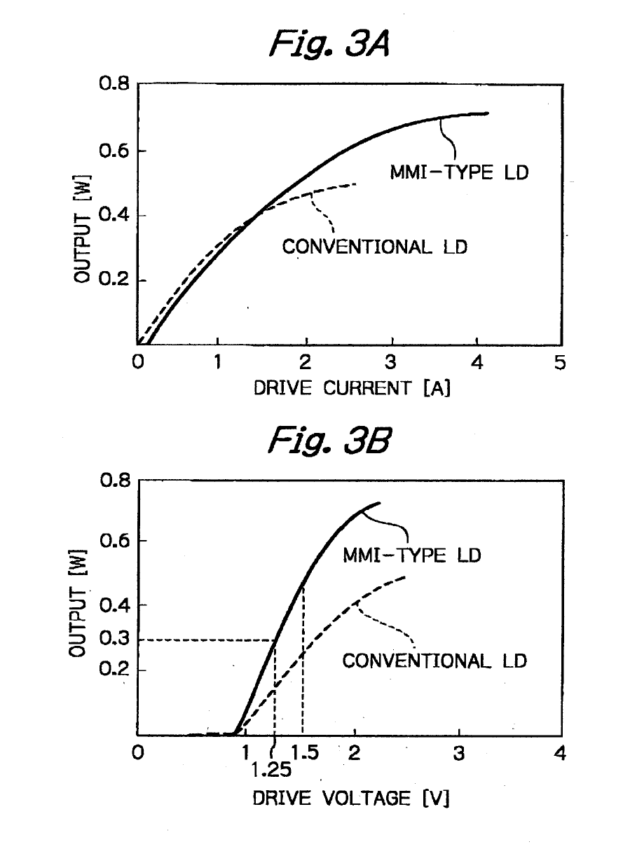

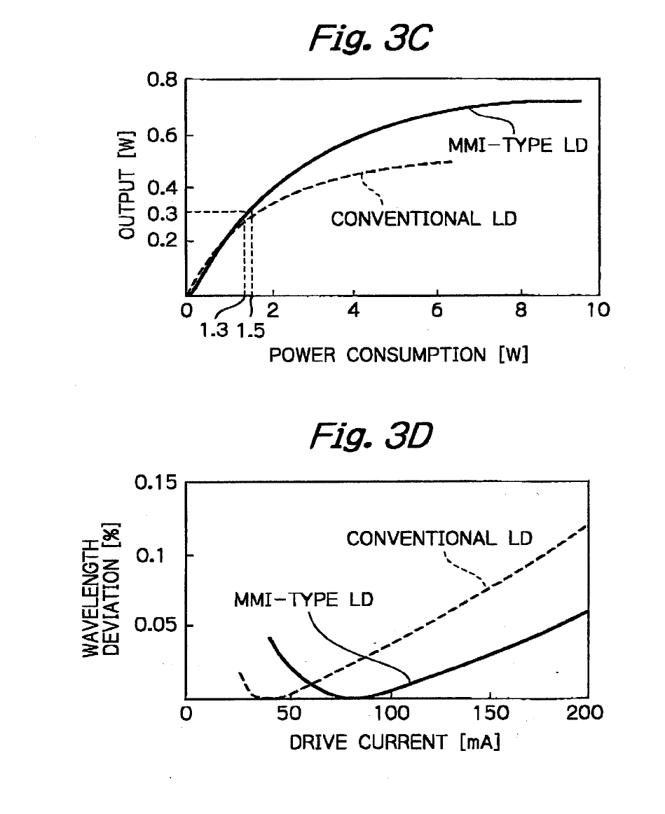

The characteristics of the MMI-type semiconductor laser diode 1 having the structure as illustrated in FIG. 2 are shown in FIGS. 3A, 3B, 3C and 3D.

As shown in FIG. 3A, the output characteristics of the MMI-type semiconductor laser diode 1 were substantially the same as those of the conventional semiconductor laser diode. Additionally, the maximum saturation output characteristics of the MMI-type semiconductor laser diode 1 were improved as compared with those of the conventional semiconductor laser diode. The output characteristics as shown in FIG. 3A were recognized by JP-A-11-068241, JP-A11-068242, Kiichi Hamamoto et at., “Single-traverse-mode Active-MMI 1,5 μm-InGaAsP Buried-Hetero Laser Diode”, European Conference on Integrated Optics, PD51-PD54, Apr. 1997 and U.S. Pat. No. 6,205,163.

As shown in FIG. 3B, output characteristics of the MMI-type semiconductor laser diode 1 that were the same as those of the conventional semiconductor laser diode were obtained by a lower drive voltage. Particularly, in the MMI-type semiconductor laser diode 1, even when the drive voltage was lower than 1.5V or about 1.25V to 1.5V, the output characteristics of higher than 0.3W were obtained. Contrary to this, in the conventional semiconductor laser diode, when the drive voltage was lower than 1.5V, the output characteristics of higher than 0.3W were never obtained. The output characteristics as shown in FIG. 3B were found by the inventors.

As shown in FIG. 3C, output characteristics of the MMI-type semiconductor laser diode 1 that were the same as those of the conventional semiconductor laser diode were obtained by a lower power consumption. Particularly, in the MMI-type semiconductor laser diode 1, even when the power consumption was lower than 1.5W or about 1.3W to 1.5W, the output characteristics of higher than 0.3W were obtained. Contrary to this, in the conventional semiconductor laser diode, when the power-consumption was lower than 1.5W, the output characteristics of higher than 0.3W were never obtained. The output characteristics as shown in FIG. 3C were also found by the inventors.

Note that if the semiconductor laser diode module includes a cooler element, the smaller the power consumption, the smaller the cooler element. Also, the smaller the cooler element, the smaller the package 10.

As shown in FIG. 3D, the wavelength deviation characteristics of the light beam of the MMI-type semiconductor laser diode 1 dependent upon the drive current were remarkably improved as compared with those of the conventional semiconductor laser diode. That is, when the drive current was smaller than 200 mA, the wavelength deviation characteristics were smaller than 0.1%. The wavelength deviation characteristics as shown in FIG. 3D were found by the inventors. Therefore, when the grating-associated optical fiber 8 is used, the fluctuation and noise in the light beam by the mode hopping phenomenon can be sufficiently suppressed, which would stabilize the operation of the MMI-type semiconductor laser diode 1. Also, since the wavelength deviation of the light beam of the MMI-type semiconductor laser diode 1 is small, the grating-associated optical fiber 8 can be a simple optical fiber, which would decrease the manufacturing cost.

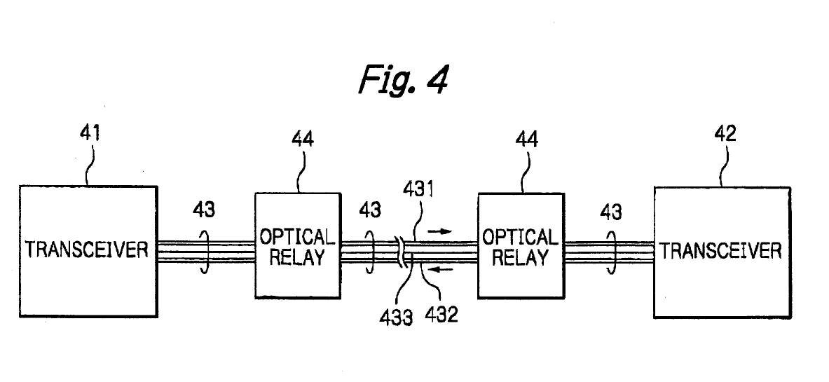

In FIG. 4, which illustrates an optical communication system to which the MMI-type semiconductor laser diode 1 of FIG. 1 is applied, two transceivers 41 and 42 are connected by a cable 43 which is constructed by an upstream optical fiber 431, a downstream optical fiber 432 and a power supply line 433. Also, optical relays 44 are positioned at intermediate points of the cable 43 between the transceivers 41 and 42. For example, the distance between the transceivers 41 and 42 is on the order of 1000 km to 10000 km, and an interval between the optical relays 44 is on the order of 10 km to 100 km.

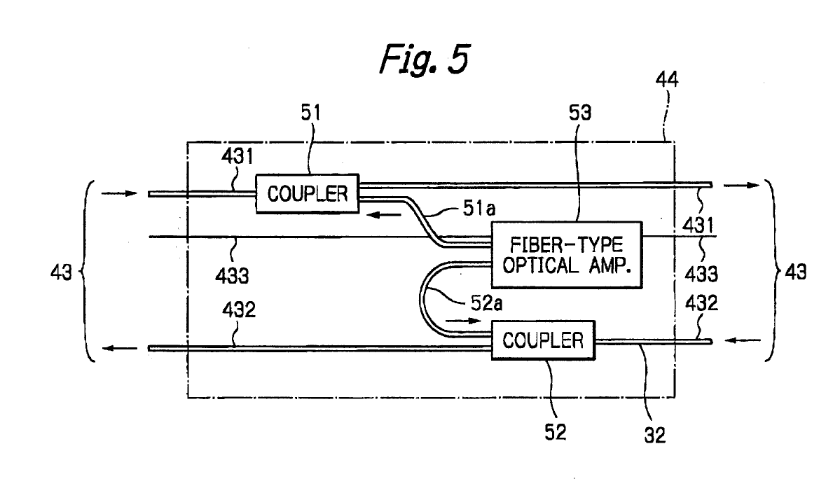

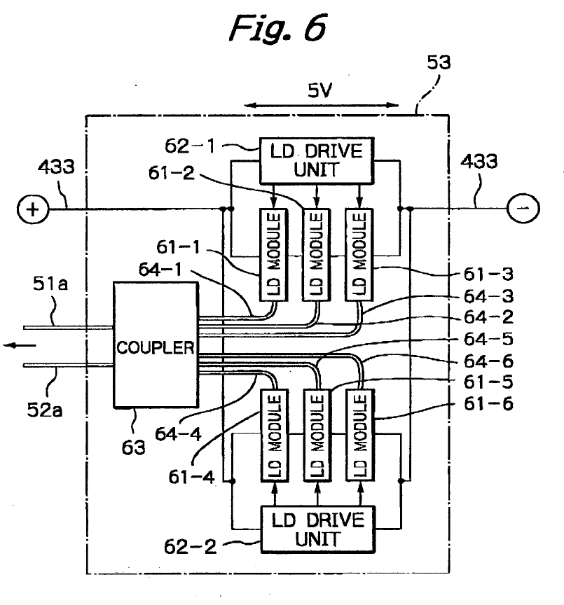

In FIG. 5, which is a detailed block circuit diagram of one of the optical relays 44 of FIG. 4, each of the optical relays 44 is constructed by a coupler 51 at the upstream optical fiber 431, a coupler 52 at the downstream optical fiber 432, and a fiber-type optical amplifier 53 powered by the power supply line 433. The fiber-type optical amplifier 53 is coupled by an optical fiber 51a to the coupler 51, so as to perform a back Raman amplification upon the upstream optical fiber 431. On the other hand, the fiber-type optical amplifier 53 is coupled by an optical fiber 52a to the coupler 52, so as to perform a back Raman amplification upon the upstream optical fiber 432.

In FIG. 6, which is a detailed block circuit diagram of the fiber-type optical amplifier 53 of FIG. 5, the fiber-type optical amplifier 53 is constructed by six MMI-type semiconductor laser diode modules 61-1, 61-2, 61-3, 61-4, 61-5 and 61-6 having the same configuration as the MMI-type semiconductor laser diode module 1 of FIG. 1, a laser diode (LD) drive unit 62-1 for driving the MMI-type semiconductor laser diode modules 61-1, 61-2 and 61-3, an LD drive unit 62-2 for driving the MMI-type semiconductor laser diodes 61-4, 61-5 and 61-6, and a coupler 63 coupled by optical fibers 64-1, 64-2, 64-3, 64-4, 64-5 and 64-6 to the MMI-type semiconductor laser diode modules 61-1, 61-2, 61-3, 61-4, 61-5 and 61-6, respectively.

Also, the MMI-type semiconductor laser diode modules 61-1, 61-2, 61-3, 61-4, 61-5 and 61-6 and the LD drive unit 62-1 and 62-2 are powered by the power supply line 433, i.e., 5V. In this case, the series of the MMI-type semiconductor diode modules 61-1, 61-2 and 61-3 are powered by 5V, and the series of the MMI-type semiconductor diode modules 61-4, 61-5 and 61-6 are powered by 5V. Further, each of the LD drive units 62-1 and 62-2 is powered by 5V.

In FIG. 6, each of the MMI-type semiconductor laser diode modules 61-1, 61-2, 61-3, 61-4, 61-5 and 61-6 has an external grating (not shown), so that the center wavelengths of the MMI-type semiconductor laser diode modules 61-1, 61-2, 61-3, 61-4, 61-5 and 61-6 are 1430 nm, 1435 nm, 1440 nm, 1445 nm, 1450 nm, 1455 nm and 1460 nm, respectively.

In FIGS. 4, 5 and 6, when the optical communication system of FIG. 4 is a submarine communication system, the fiber-type optical amplifier 63 is powered only by the power supply line 433. In this case, as stated above, in view of the breakdown of the cable 43, the maximum voltage of the power supply line 433 is 5V for the series of the semiconductor laser diode modules 61-1, 61-2 and 61-3 (61-4, 61-5 and 61-6).

Generally, in order to flatten the gain, i.e., in order to improve the transmission characteristics and the multiplexity of wavelengths, the output of each semiconductor laser diode module incorporated into the fiber-type optical amplifier 53 should be increased or the total number of semiconductor laser modules incorporated into the fiber-type optical amplifier 53.

In view of the foregoing, since the MMI-type semiconductor laser diode module 1 of FIG. 1 for emitting 0.3W or higher output is driven by a drive voltage of lower than 1.5V, the three MMI-type semiconductor laser diode modules 61-1, 61-2 and 61-3 (61-4, 61-5 and 61-6) can be sufficiently connected in series. Even in this case, the total drive voltage is at most 4.5V. Also, the number of the series of three MMI-type semiconductor laser diode modules is two in the same way as in the conventional optical system.

On the other hand, in case of conventional semiconductor laser diode modules, each of the semiconductor laser diode modules requires a drive voltage of higher than 2V or about 2V to 2.5V as stated above. Therefore, only two semiconductor laser diode modules can be connected in series. Note that, if the number of series of the two semiconductor laser diode modules is three or more, the total number of semiconductor laser diode modules incorporated into the fiber-type optical amplifier 53 may be increased; however, in this case, a current flowing through each fiber-type optical amplifier is increased which results in a voltage drop in the power supply line 433 by the increased current, thus substantially decreasing the drive voltage applied to one fiber-type optical amplifier to be lower than 5V. After all, the number of series of semiconductor laser diode modules cannot be increased.

Thus, in case where the drive voltage is 5V per series of the semiconductor laser diode modules 61-1, 61-2 and 61-3 (61-4, 61-5 and 61-6), the configuration of the 2×3 MMI-type semiconductor laser diode modules 61-1, 61-2, 613, 61-4, 61-5 and 61-6 is helpful in high speed, long-distance and large capacity optical communication systems such as a submarine cable DWDM optical communication system having a bit rate of higher than 40 Gbps.

In the above-described first embodiment, the grating-associated optical fiber 8 can be replaced by a simple optical fiber with a waveguide grating. Also, instead of externally providing the grating 8a in the optical fiber 8 or the waveguide grating, a grating can be internally provided in the MMI-type semiconductor laser diode module 1 (61-1, 61-2, 61-3, 61-4, 61-5 and 61-6). Further, since the MMI-type semiconductor laser diode modules 1 (61-1, 61-2, 61-3, 61-4, 61-5 and 61-6) per se have an MMI-type waveguide for stabilizing the wavelength, a means for stabilizing the wavelength may not be provided. Additionally, in the semiconductor laser diode module of FIG. 1, the carrier 3 can include a cooler element such as a Peltier element when required, however, such a cooler element is not included in the carrier 3 for a submarine communication system. Still further, the package 10 can be of a can type as well as of a butterfly-type.

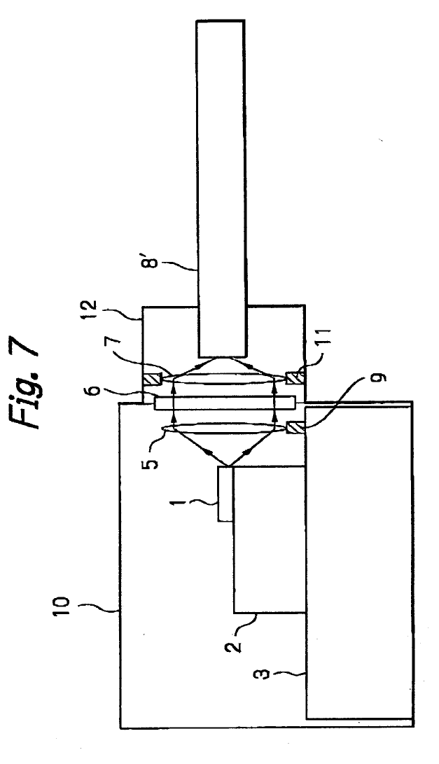

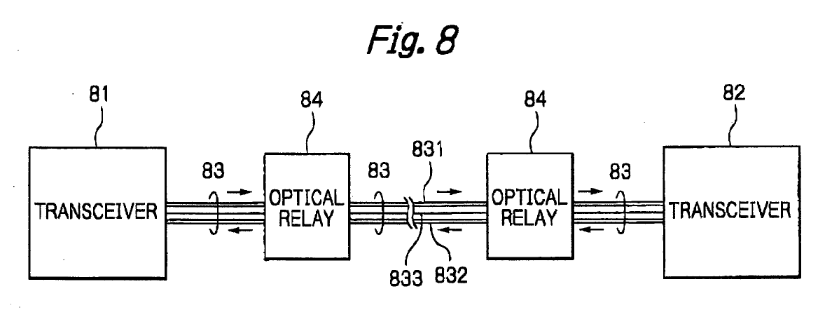

In FIG. 7, which illustrates a second embodiment of the semiconductor laser diode module according to the present invention, the grating-associated optical fiber 8 of FIG. 1 is replaced by a single-mode optical fiber 8′.

In FIG. 8, which illustrates an optical communication system to which the MMI-type semiconductor laser diode 1 of FIG. 7 is applied, two transceivers 81 and 82 are connected by a cable 83 which is constructed by an upstream Er-doped optical fiber 831, a downstream Er-doped optical fiber 832 and a power supply line 833. Also, optical relays 84 are positioned at intermediate points of the cable 83 between the transceivers 81 and 82. For example, the distance between the transceivers 81 and 82 is on the order of 1000 km to 10000 km, and an interval between the optical relays 84 is on the order of 10 km to 100 km.

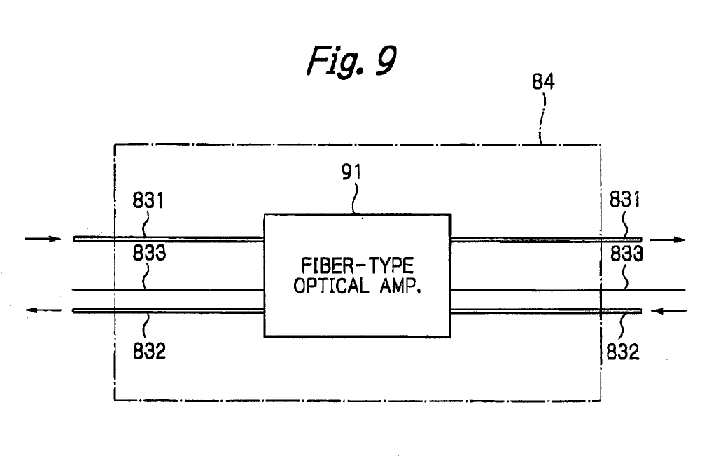

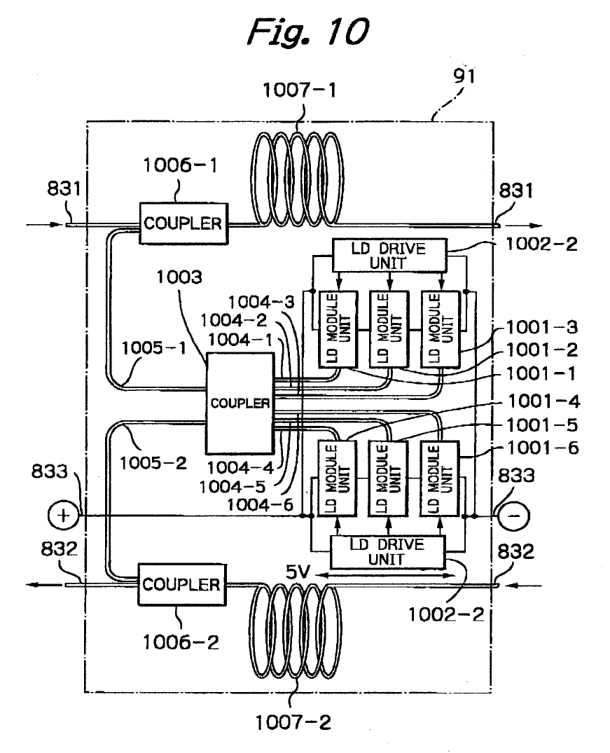

In FIG. 9, which is a detailed block circuit diagram of one of the optical relays 84 of FIG. 8, each of the optical relays 84 is constructed by a fiber-type optical amplifier 91 powered by the power supply line 833. The fiber-type optical amplifier 841 is coupled to the Er-doped optical fibers 831 and 832, so as to perform an optical amplification thereupon by Er-doped optical fibers 1007-1 and 1007-2 (not shown in FIG. 9, but in FIG. 10),

In FIG. 10, which is a detailed block circuit diagram of the fiber-type optical amplifier 91 of FIG. 9, the fiber-type optical amplifier 91 is constructed by six MMI-type semiconductor laser diode modules 1001-1, 1001-2, 1001-3, 1001-4, 1001-5 and 1001-6 having the same configuration as the MMI-type semiconductor laser diode module of FIG. 7, a drive unit 1002-1 for driving the MMI-type semiconductor laser diode modules 1001-1, 1001-2 and 1001-3, an LD drive unit 1002-2 for driving the MMI-type semiconductor laser diodes 1001-4, 1001-5 and 1001-6, and a coupler 1003 coupled by optical fibers 1004-1, 1004-2, 1004-3, 1004-4, 1004-5 and 1004-6 to the MMI-type semiconductor laser diode modules 1001-1, 1001-2, 1001-3, 1001-4, 1001-5 and 1001-6, respectively.

Also, the coupler 1003 is coupled by an optical fiber 1005-1 to a coupler 1006-1 at the upstream Er-doped optical fiber 831 where the Er-doped optical fiber 1007-1 for amplification is also provided, and the coupler 1003 is coupled by an optical fiber 1005-2 to a coupler 1006-2 at the downstream Er-doped optical fiber 832 where the Er-doped optical fiber 1007-2 for amplification is also provided.

Also, the MMI-type semiconductor laser diode modules 1001-1, 1001-2, 1001-3, 1001-4, 1001-5 and 1001-6 and the LD drive unit 1002-1 and 1002-2 are powered by the power supply line 833, i.e., 5V. In this case, the series of the MMI-type semiconductor diode modules 1001-1, 1001-2 and 1001-3 are powered by 5V, and the series of the MMI-type semiconductor diode modules 1001-4, 1001-5 and 1001-6 are powered by 5V.

In FIG. 10, the center wavelengths of the MMI-type semiconductor laser diode modules 1001-1, 1001-2, 1001-3, 1001-4, 1001-5 and 1001-6 are around 1480 nm for the excited energy of-the Er-doped optical fibers.

In FIGS. 8, 9 and 10, when the optical communication system of FIG. 8 is a submarine communication system, the fiber-type optical amplifier 91 is powered only by the power supply line 833. In this case, as stated above, in view of the breakdown of the cable 83, the maximum voltage of the power supply line 833 is 5V.

Even in FIG. 10, since the MMI-type semiconductor laser diode module of FIG. 7 for emitting 0.3W or higher output is driven by a drive voltage of lower than 1.5V, the three MMI-type semiconductor laser diode modules 1001-1, 1001-2 and 1001-3 (1001-4, 1001-5 and 1001-6) can be sufficiently connected in series. Even in this case, the total drive voltage is at most 4.5V. Also, the number of the series of three MMI-type semiconductor laser diode modules is two in the same way as in the conventional optical system.

Thus, in case where the drive voltage is 5V per series of the semiconductor laser diode modules 1001-1, 1001-2 and 1001-3 (1001-4, 1001-6 and 1001-6), the configuration of the 2 series of 3 MMI-type semiconductor laser diode modules 1001-1, 1001-2, 1001-3, 1001-4, 1001-5 and 1001-6 are helpful in high speed, long-distance and large capacity optical communication systems such as a submarine cable DWDM optical communication system having a bit rate of higher than 40 Gbps.

In the above-described second embodiment, the Er-doped optical fibers can be other rare earth element added optical fibers. In this case, the center wavelengths of the MMI-type semiconductor laser diode modules 10101-1, 1001-2, 1001-3, 1001-4, 1001-5 and 1001-6 are suitable for the excited energy of the other rare earth element, for example, around 980 nm.

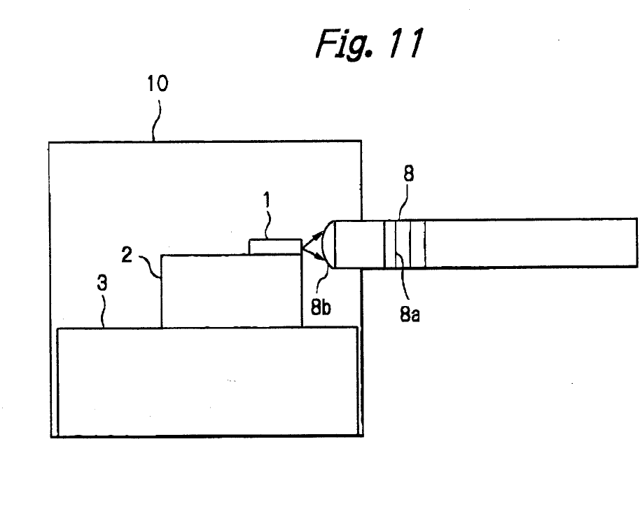

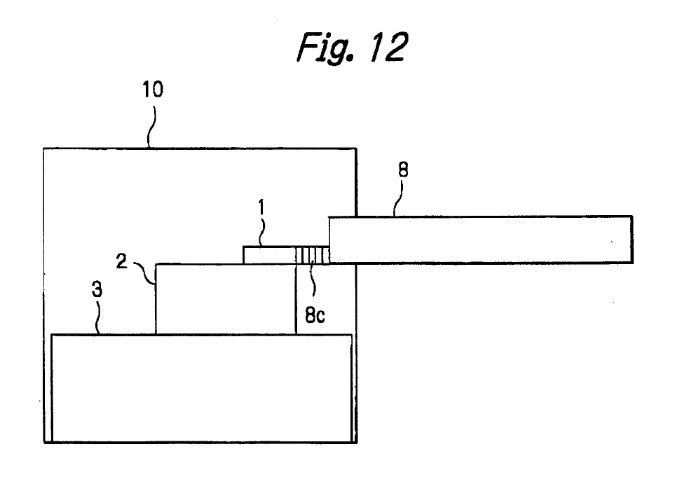

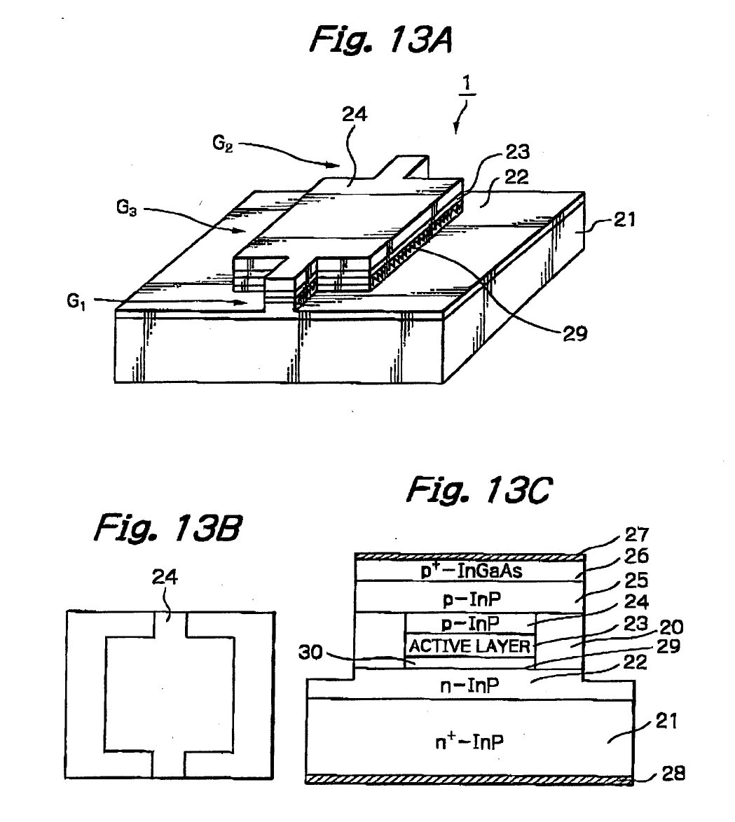

Also, in FIGS. I and 7, the semiconductor laser diode 1 can be coupled directly to the optical fiber 8(8′) without the collimating lens 5, the glass element 6 and the coupling lens 7. In this case, as illustrated in FIG. 11, a spherical lens 8b is provided at an end of the optical fiber 8. Also, as illustrated in FIG. 12, a waveguide grating 8c as another external grating can be provided instead of the external grating 8a. Further, as illustrated in FIGS. 13A, 13B and 13C, a grating 29 can be internally provided in the semiconductor laser diode module instead of the grating 8a or the waveguide grating 8c. Note that reference numeral 30 designates an n-type InGaAsP optical waveguide layer.

Additionally, in FIG. 4 (FIG. 8), only one of the optical fibers 431 and 432 (831 and 832) can be provided. In this case, the coupler 63 of FIG. 6(1003 of FIG. 10) has only to be provided with one output port.

Further, in the above-described embodiments, the number of MMI-type semiconductor modules in each series can be 4 or more as the voltage the power supply line is changed.

As explained above, in a semiconductor laser diode module according to the present invention a wavelength-stabilized output signal can be generted at a lower drive voltage and a lower power consumption.

1. A semiconductor laser diode module comprising a semiconductor laser diode including a multi-mode interference type active waveguide.

2. The semiconductor laser diode module as set forth in claim 1, wherein said semiconductor laser diode is operated at a drive voltage of lower than 1.5V.

3. The semiconductor laser diode module as set forth in claim 1 wherein said semiconductor laser diode is operated at a power consumption of lower than 1.5W.

4. The semiconductor laser diode module as set forth in claim 1, wherein a wavelength deviation of said semiconductor laser diode is smaller than 0.1% at a drive current of lower than 200 mA.

5. The semiconductor laser diode module as set forth in claim 1, wherein said multi-mode interference type active waveguide is a 1×N (N=1, 2, . . . ) multi-mode interference type active waveguide,
said semiconductor laser diode further including:
a one-port single-mode waveguide connected to an end of said 1×N multi-mode interference type active waveguide and having one port at a front facet of said semiconductor laser diode;
an N-port single-mode waveguide connected to another end of said 1×N multi-mode interference type active waveguide and having N ports at a rear facet of said semiconductor laser diode;
an anti-reflection coating applied to the front facet of said semiconductor laser diode; and
a high-reflection coating applied to the rear face of said semiconductor laser diode.

6. The semiconductor laser diode module as set forth in claim 1, further comprising a grating-associated optical fiber for stabilizing a wavelength of a light beam from said semiconductor laser diode.

7. The semiconductor laser diode module as set forth in claim 1, further comprising an optical fiber for stabilizing a wavelength of a light beam from said semiconductor laser diode, said optical fiber comprising no grating.

8. The semiconductor laser diode module as set forth in claim 1, wherein said semiconductor laser diode is with an internally provided grating.

9. The semiconductor laser diode module as set forth in claim 1, wherein said semiconductor laser diode is with an externally provided waveguide grating.

10. A fiber-type optical amplifier for performing a back Raman amplification upon at least one optical fiber, comprising:
a power supply line;
at least one series of semiconductor laser diode modules powered by said power supply line; and
a coupler for coupling light beams of said semiconductor laser diode modules to generate a coupled light beam,
each of said semiconductor laser diode modules comprising a semiconductor laser diode including a multi-mode interference type active waveguide.

11. The fiber-type optical amplifier as set forth in claim 10, wherein said semiconductor laser diode is operated at a drive voltage of lower than 1.5V.

12. The fiber-type optical amplifier as set forth in claim 10, wherein said semiconductor laser diode is operated at a power consumption of lower than 1.5W.

13. The fiber-type optical amplifier as set forth in claim 10, wherein a wavelength deviation of said semiconductor laser diode is smaller than 0.1% at a drive current of lower than 200 mA.

14. The fiber-type optical amplifier as set forth in claim 10, wherein said multi-mode interference type active waveguide is a 1×N (N=1, 2, . . . ) multi-mode interference type active waveguide,
said semiconductor laser diode further including:
one-port single-mode waveguide connected to an end of said 1×N multi-mode interference type active waveguide and having one port at a front facet of said semiconductor laser diode;
an N-port single-mode waveguide connected to another end of said 1×N multi-mode interference type active waveguide and having N ports at a rear facet of said semiconductor laser diode;
an anti-reflection coating applied to the front facet of said semiconductor laser diode; and
a high-reflection coating applied to the rear face of said semiconductor laser diode.

15. The fiber-type optical amplifier as set forth in claim 10, wherein each of said semiconductor laser diode modules further comprises a grating-associated optical fiber for stabilizing a wavelength of a light beam from said semiconductor laser diode.

16. The fiber-type optical amplifier as set forth in claim 10, wherein each of said semiconductor laser diode modules further comprises an optical fiber for stabilizing a wavelength of a light beam from said semiconductor laser diode, said optical fiber comprising no grating.

17. The fiber-type optical amplifier as set forth in claim 10, wherein said semiconductor laser diode is with an internally provided grating.

18. The fiber-type optical amplifier as set forth in claim 10, wherein said semiconductor laser diode is with an externally provided waveguide grating.

19. A fiber-type optical amplifier for performing a amplification upon at least one rare earth element doped optical fiber, comprising:
a power supply line;
at least one series of semiconductor laser diode modules powered by said power supply line;
a first coupler for coupling light beams of said semiconductor laser diode modules to generate a coupled light beam for said rare earth element doped optical fiber; and
a second coupler for stabilizing a wavelength of said coupled light beam at said rare earth element doped optical fiber,
each of said semiconductor laser diode modules comprising a semiconductor laser diode including a multi-mode interference type active waveguide.

20. The fiber-type optical amplifier as set forth in claim 19, wherein said semiconductor laser diode is operated at a drive voltage of lower than 1.5V.

21. The fiber-type optical amplifier as set forth in claim 19, wherein said semiconductor laser diode is operated at a power consumption of lower than 1.5W.

22. The fiber-type optical amplifier as set forth in claim 19, wherein a wavelength deviation of said semiconductor laser diode is smaller than 0.1% at a drive current of lower than 200 mA.

23. The fiber-type optical amplifier as set forth in claim 19, wherein said multi-mode interference type active waveguide is a 1×N (N=1, 2, . . . ) multi-mode interference type active waveguide,
said semiconductor laser diode further including:
a one-port single-mode waveguide connected to an end of said 1×N multi-mode interference type active waveguide and having one port at a front facet of said semiconductor laser diode;
an N-port single-mode waveguide connected to another end of said 1×N multi-mode interference type active waveguide and having N ports at a rear facet of said semiconductor laser diode;
an anti-reflection coating applied to the front facet of said semiconductor laser diode; and
a high-reflection coating applied to the rear face of said semiconductor laser diode.

24. The fiber-type optical amplifier as set forth in claim 19, wherein each of said semiconductor laser diode modules further comprises a grating-associated optical fiber for stabilizing a wavelength of a light beam from said semiconductor laser diode.

25. The fiber-type optical amplifier as set forth in claim 19, wherein each of said semiconductor laser diode modules further comprises an optical fiber for stabilizing a wavelength of a light beam from said semiconductor laser diode, said optical fiber comprising no grating.

26. The fiber-type optical amplifier as set forth in claim 19, wherein said semiconductor laser diode is with an internally provided grating.

27. The fiber-type optical amplifier as set forth in claim 19, wherein said semiconductor laser diode is with an externally provided waveguide grating.

28. An optical relay positioned at least one optical fiber along with a power supply line, said optical relay comprising:
a fiber-type optical amplifier for performing a Raman amplification upon said optical fiber; and
at least one first coupler, positioned at said optical fiber, for stabilizing a wavelength of a light beam from said fiber-type optical fiber,
said fiber-type optical amplifier comprising:
at least one series of semiconductor laser diode modules powered by said power supply line; and
a second coupler for coupling light beams of said semiconductor laser diode modules to generate a coupled light beam,
each of said semiconductor laser diode modules comprising a semiconductor laser diode including a multi-mode interference type active waveguide.

29. The optical relay as set forth in claim 28, wherein said semiconductor laser diode is operated at a drive voltage of lower than 1.5V.

30. The optical relay as set forth in claim 28, wherein said semiconductor laser diode is operated at a power consumption of lower than 1.5W.

31. The optical relay as set forth in claim 28, wherein a wavelength deviation of said semiconductor laser diode is smaller than 0.1% at a drive current of lower than 200 mA.

32. The optical relay as set forth in claim 28, wherein said multi-mode interference type active waveguide is a 1×N (N=1, 2, . . . ) multi-mode interference type active waveguide,
said semiconductor laser diode further including:
a one-port single-mode waveguide connected to an end of said 1×N multi-mode interference type active waveguide and having one port at a front facet of said semiconductor laser diode;
an N-port single-mode waveguide connected to another end of said 1×N multi-mode interference type active waveguide and having N ports at a rear facet of said semiconductor laser diode;
an anti-reflection coating applied to the front facet of said semiconductor laser diode; and
a high-reflection coating applied to the rear face of said semiconductor laser diode.

33. The optical relay as set forth in claim 28, wherein each of said semiconductor laser diode modules further comprises a grating-associated optical fiber for stabilizing a wavelength of a light beam from said semiconductor laser diode.

34. The optical relay as set forth in claim 28, wherein each of said semiconductor laser diode modules further comprises an optical fiber for stabilizing a wavelength of a light beam from said semiconductor laser diode, said optical fiber comprising no grating.

35. The optical relay as set forth in claim 28, wherein said semiconductor laser diode is with an internally provided grating.

36. The optical relay as set forth in claim 28, wherein said semiconductor laser diode is with an externally provided waveguide grating.

37. An optical relay positioned at least one rare earth element doped optical fiber along with a power supply line, said optical relay comprising a fiber-type optical amplifier for performing an amplification upon said rare earth element doped optical fiber,
said fiber-type optical amplifier comprising:
at least one series of semiconductor laser diode modules powered by said power supply line;
a first coupler for coupling light beams of said semiconductor laser diode modules to generate a coupled light beam for said rare earth element doped optical fiber; and
a second coupler for stabilizing a wavelength of said coupled light beam at said rare earth element doped optical fiber,
each of said semiconductor laser diode modules comprising a semiconductor laser diode including a multi-mode interference type active waveguide.

38. The optical relay as set forth in claim 37, wherein said semiconductor laser diode is operated at a drive voltage of lower than 1.5V.

39. The optical relay as set forth in claim 37, wherein said semiconductor laser diode is operated at a power consumption of lower than 1.5W.

40. The optical relay as set forth in claim 37, wherein a wavelength deviation of said semiconductor laser diode is smaller than 0.1% at a drive current of lower than 200 mA.

41. The optical relay as set forth in claim 37, wherein said multi-mode interference type active waveguide is a 1×N (N=1, 2, . . . ) multi-mode interference type active waveguide,
said semiconductor laser diode further including:
a one-port single-mode waveguide connected to an end of said 1×N multi-mode interference type active waveguide and having one port at a front facet of said semiconductor laser diode;
an N-port single-mode waveguide connected to another end of said 1×N multi-mode interference type active waveguide and having N ports at a rear facet of said semiconductor laser diode;
an anti-reflection coating applied to the front facet of said semiconductor laser diode; and
a high-reflection coating applied to the rear face of said semiconductor laser diode.

42. The optical relay as set forth in claim 37, wherein each of said semiconductor laser diode modules further comprises a grating-associated optical fiber for stabilizing a wavelength of a light beam from said semiconductor laser diode.

43. The optical relay as set forth in claim 37, wherein each of said semiconductor laser diode modules further comprises an optical fiber for stabilizing a wavelength of a light beam from said semiconductor laser diode, said optical fiber comprising no grating.

44. The optical relay as set forth in claim 37, wherein said semiconductor laser diode is with an internally provided grating.

45. The optical relay as set forth in claim 37, wherein said semiconductor laser diode is with an externally provided waveguide grating.

46. An optical communication system comprising:
at least two transceivers;
at least one optical fiber along with a power supply line linked between said transceivers; and
at least one optical relay positioned at said optical fiber,
said optical relay comprising:
a fiber-type optical amplifier for performing a Raman amplification upon said optical fiber; and
at least one first coupler, positioned at said optical fiber, for stabilizing a wavelength of a light beam from said fiber-type optical fiber,
said fiber-type optical amplifier comprising:
at least one series of semiconductor laser diode modules powered by said power supply line; and
a second coupler for coupling light beams of said semiconductor laser diode modules to generate a coupled light beam,
each of said semiconductor laser diode modules comprising a semiconductor laser diode including a multi-mode interference type active waveguide.

47. The optical communication system as set forth in claim 46, wherein said semiconductor laser diode is operated at a drive voltage of lower than 15V.

48. The optical communication system as set forth in claim 46, wherein said semiconductor laser diode is operated at a power consumption of lower than 1.5W.

49. The optical communication system as set forth in claim 46, wherein a wavelength deviation of said semiconductor laser diode is smaller than 0.1% at a drive current of lower than 200 mA.

50. The optical communication system as set forth in claim 46, wherein said multi-mode interference type active waveguide is a 1×N (N=1, 2, . . . ) multi-mode interference type active waveguide,
said semiconductor laser diode further including:
a one-port single-mode waveguide connected to an end of said 1×N multi-mode interference type active waveguide and having one port at a front facet of said semiconductor laser diode;
an N-port single-mode waveguide connected to another end of said 1×N multi-mode interference type active waveguide and having N ports at a rear facet of said semiconductor laser diode;
an anti-reflection coating applied to the front facet of said semiconductor laser diode; and
a high-reflection coating applied to the rear face of said semiconductor laser diode.

51. The optical communication system as set forth in claim 46, wherein each of said semiconductor laser diode modules further comprises a grating-associated optical fiber for stabilizing a wavelength of a light beam from said semiconductor laser diode.

52. The optical communication system as set forth in claim 46, wherein each of said semiconductor laser diode modules further comprises an optical fiber for stabilizing a wavelength of a light beam from said semiconductor laser diode, said optical fiber comprising no grating.

53. The optical communication system as set forth in claim 46, wherein said semiconductor laser diode is with an internally provided grating.

54. The optical communication system as set forth in claim 46, wherein said semiconductor laser diode is with an externally provided waveguide grating.

55. An optical communication system comprising:
at least two transceivers;
at least one rare earth element doped optical fiber along with a power supply line linked between said transceivers; and
at least one optical relay positioned at said rare earth element doped optical fiber,
said optical relay comprising a fiber-type optical amplifier for performing an amplification upon said rare earth element doped optical fiber,
said fiber-type optical amplifier comprising:
at least one series of semiconductor laser diode modules powered by said power supply line;
a first coupler for coupling light beams of said semiconductor laser diode modules to generate a coupled light beam for said rare earth element doped optical fiber; and
a second coupler for stabilizing a wavelength of said coupled light beam at said rare earth element doped optical fiber,
each of said semiconductor laser diode modules comprising a semiconductor laser diode including a multi-mode interference type active waveguide.

56. The optical communication system as set forth in claim 57, wherein said semiconductor laser diode is operated at a drive voltage of lower than 1.5V.

57. The optical communication system as set forth in claim 55, wherein said semiconductor laser diode is operated at a power consumption of lower than 1.5W.

58. The optical communication system as set forth in claim 55, wherein a wavelength deviation of said semiconductor laser diode is smaller than 0.1% at a drive current of lower than 200 mA.

59. The optical communication system as set forth in claim 55, wherein said multi-mode interference type active waveguide is a 1×N (N=1, 2, . . . ) multi-mode interference type active waveguide,
said semiconductor laser diode further including:
a one-port single-mode waveguide connected to an end of said 1×N multi-mode interference type active waveguide and having one port at-a front facet of said semiconductor laser diode;
an N-port single-mode waveguide connected to another end of said 1×N multi-mode interference type active waveguide and having N ports at a rear facet of said semiconductor laser diode;
an anti-reflection coating applied to the front facet of said semiconductor laser diode; and
a high-reflection coating applied to the rear face of said semiconductor laser diode.

60. The optical communication system as set forth in claim 55, wherein each of said semiconductor laser diode modules further comprises a grating-associated optical fiber for stabilizing a wavelength of a light beam from said semiconductor laser diode.

61. The optical communication system as set forth in claim 55, wherein each of said semiconductor laser diode modules further comprises an optical fiber for stabilizing a wavelength of a light beam from said semiconductor laser diode, said optical fiber comprising no grating.

62. The optical communication system as set forth in claim 55, wherein said semiconductor laser diode is with an internally provided grating.

63. The optical communication system as set forth in claim 56, wherein said semiconductor laser diode is with an externally provided waveguide grating.
